(19) United States
(12) Patent Application Publication
(10) Pub. No.: US 2019/0048460 A1
(43) Pub. Date: Feb. 14, 2019

(54) Evaporation Crucible and Evaporation System

(71) Applicant: WUHAN CHINA STAR OPTOELECTRONICS SEMICONDUCTOR DISPLAY TECHNOLOGY CO., LTD., Wuhan (CN)

(72) Inventor: Chao XU, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 15/576,857

(22) PCT Filed: Oct. 19, 2017
(86) PCT No.: PCT/CN2017/106818

§ 371 Date: Nov. 27, 2017

(30) Foreign Application Priority Data
Aug. 14, 2017 (CN) 201710692335.8

(51) Int. Cl. C23C 14/24

(52) U.S. Cl. CPC C23C 14/243

(57) ABSTRACT

An evaporation system and an evaporation crucible are provided. The evaporation crucible includes a crucible body and at least two heating means wounded around the crucible body. The crucible body includes at least two cylindrical structures having different diameters. The crucible body is used to contain an evaporation material. The heating means is disposed respectively corresponding to the cylindrical structures. The heating means heats the evaporation material in the corresponding cylindrical structure.

### BACKGROUND

### 1. Field of the Invention

The present disclosure relates to an equipment manufacturing technology, more particularly, to an evaporation crucible and an evaporation system including the evaporation crucible.

### 2. Description of the Related Art

Organic light-emitting diode (OLED) displays have plenty of advantages, such as high brightness, fast response, low power consumption, being flexible, etc., and have played an increasingly important role in today's flat panel display market. OLED displays represent the development trend of the next-generation displays. As compared with liquid crystal displays (LCDs), the biggest advantages that the OLED displays have are being able to be manufactured in a large size, being ultra-thin, flexible and transparent.

The more mature technology for manufacturing OLEDs in the related art utilizes a small molecule evaporation process. However, in the evaporation process in the related art, a point source usually adopts a cylindrical crucible, and a heating wire is integrally heated. Because a temperature difference in the crucible is fixed, the longer the longitudinal length of the crucible is, the more difficult the temperature difference can be controlled. Therefore, one section heating would cause a greater temperature difference between an upper end and a lower end of the crucible, thus wasting the material.

### SUMMARY

The present disclosure provides an evaporation crucible and an evaporation system including the evaporation crucible. Not only can the excessively big temperature differences in the horizontal direction and longitudinal direction of the evaporation crucible in the evaporation system in the related art be improved, but the waste of evaporation material can be reduced. The material utilization rate is increased to reduce the production cost.

In a first aspect of the present disclosure, an evaporation crucible includes a crucible body and at least two heating means wounded around the crucible body. The crucible body includes at least two cylindrical structures. The cylindrical structures have different diameters. The crucible body is used to contain an evaporation material. The heating means are disposed respectively corresponding to the cylindrical structures. The heating means heats the evaporation material in the corresponding cylindrical structure. The heating means further include a temperature measurement and control part configured to measure and control a heating temperature of at least two heating areas, separately.

According to an embodiment of the present disclosure, the present disclosure, the evaporation crucible further comprises at least two sieve discs, the sieve discs respectively correspond to the cylindrical structures, each of the sieve discs is disposed on top of the corresponding cylindrical structure and is configured to uniform flow of the evaporation material in the crucible body.

According to another embodiment of the present disclosure, both the sieve discs and the crucible body are made of titanium.

According to another embodiment of the present disclosure, each of the cylindrical structures is a heating area. The crucible body comprises three heating areas, the three heating areas are a first heating area, a second heating area and a third heating area. The first heating area is a bottom area of the crucible body, the second heating area is a middle area of the crucible body, and the third heating area is a top area of the crucible body. A diameter of the first heating area is shorter than a diameter of the second heating area, and the diameter of the second heating area is shorter than a diameter of the third heating area.

According to another embodiment of the present disclosure, a height of the first heating area occupies 10% of a height of the crucible body, and a height of the third heating area occupies 15% of the height of the crucible body.

According to another embodiment of the present disclosure, the sieve discs comprise a first sieve disc, a second sieve disc and a third sieve disc. The first sieve disc corresponds to the first heating area, the second sieve disc corresponds to the second heating area, and the third sieve disc corresponds to the third heating area. An area of the first sieve disc is shorter than an area of the second sieve disc, and the area of the second sieve disc is shorter than an area of the third sieve disc.

According to another embodiment of the present disclosure, a diameter of circular openings of a first sieve disc is longer than a diameter of circular openings of a second sieve disc, and the diameter of circular openings of the second sieve disc is longer than a diameter of circular openings of a first sieve disc.

According to another embodiment of the present disclosure, the heating means comprise a first heating means, a second heating means and a third heating means disposed along a longitudinal direction. The first heating means, second heating means and third heating means are disposed respectively around the first heating area, the second heating area and the third heating area so that separate and uniform heating of the first heating area, the second heating area and the third heating area are achieved.

In a second aspect of the present disclosure, an evaporation crucible includes a crucible body and at least two heating means wounded around the crucible body. The crucible body includes at least two cylindrical structures. The cylindrical structures have different diameters. The crucible body is used to contain an evaporation material. The heating means are disposed respectively corresponding to the cylindrical structures. The heating means heats the evaporation material in the corresponding cylindrical structure.

According to an embodiment of the present disclosure, the present disclosure, the evaporation crucible further comprises at least two sieve discs, the sieve discs respectively correspond to the cylindrical structures, each of the sieve discs is disposed on top of the corresponding cylindrical structure and is configured to uniform flow of the evaporation material in the crucible body.

According to another embodiment of the present disclosure, both the sieve discs and the crucible body are made of titanium.

According to another embodiment of the present disclosure, each of the cylindrical structures is a heating area. The crucible body comprises three heating areas, the three heating areas are a first heating area, a second heating area and a third heating area. The first heating area is a bottom area of the crucible body, the second heating area is a middle area of the crucible body, and the third heating area is a top area of the crucible body. A diameter of the first heating area is shorter than a diameter of the second heating area, and the diameter of the second heating area is shorter than a diameter of the third heating area.

According to another embodiment of the present disclosure, a height of the first heating area occupies 10% of a height of the crucible body, and a height of the third heating area occupies 15% of the height of the crucible body.

According to another embodiment of the present disclosure, the sieve discs comprise a first sieve disc, a second sieve disc and a third sieve disc. The first sieve disc corresponds to the first heating area, the second sieve disc corresponds to the second heating area, and the third sieve disc corresponds to the third heating area. An area of the first sieve disc is shorter than an area of the second sieve disc, and the area of the second sieve disc is shorter than an area of the third sieve disc.

According to another embodiment of the present disclosure, a diameter of circular openings of a first sieve disc is longer than a diameter of circular openings of a second sieve disc, and the diameter of circular openings of the second sieve disc is longer than a diameter of circular openings of a first sieve disc.

According to another embodiment of the present disclosure, the heating means comprise a first heating means, a second heating means and a third heating means disposed along a longitudinal direction. The first heating means, second heating means and third heating means are disposed respectively around the first heating area, the second heating area and the third heating area so that separate and uniform heating of the first heating area, the second heating area and the third heating area are achieved.

In a third aspect of the present disclosure, an evaporation system including an evaporation crucible as provided above is disclosed.

The present disclosure provides an evaporation crucible and an evaporation system including the evaporation crucible. Not only can the excessively big temperature differences in the horizontal direction and longitudinal direction of the evaporation crucible in the evaporation system in the related art be improved, but the waste of evaporation material can be reduced. The material utilization rate is increased to reduce the production cost.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a structure of an evaporation crucible in the related art.

FIG. 2 is a schematic diagram of a structure of an evaporation crucible according to one embodiment of the present disclosure.

FIG. 3 is a schematic diagram of another structure of an evaporation crucible according to one embodiment of the present disclosure.

FIG. 4 is a schematic diagram of structures of sieve discs according to one embodiment of the present disclosure.

### DESCRIPTION OF THE EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

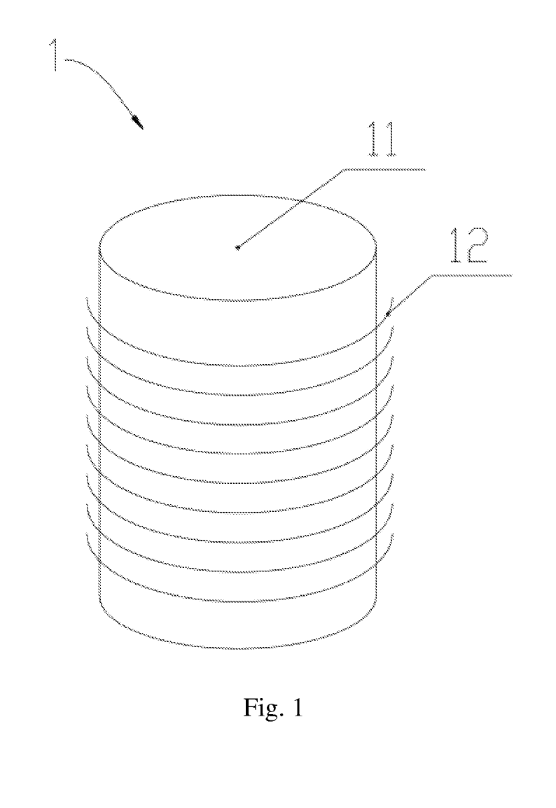

FIG. 1 is a schematic diagram of a structure of an evaporation crucible in the related art. In an evaporation process in the related art, when an evaporation crucible 1 is used and heated, an evaporation material contained in a crucible body 11 is evaporated until completely consumed. An amount of material to be placed is determined by a capacity of the crucible body 11. However, since a heating means 12 of the evaporation crucible 1 in the related art is integrally heated, a temperature difference in the evaporation crucible 1 is fixed. The greater a longitudinal length of the crucible body 11 is, the greater a temperature difference between an evaporation material in the crucible body 11 is. Therefore, the evaporation material tends to melt in a non-uniform manner. Sudden boiling due to a length of the crucible body 11 causes an unstable rate, and non-uniform heat conduction inside the evaporation material causes cracks of the evaporation material so as to form defects. As a result, an effective utilization rate of the evaporation material is from 10% to 80%, thus wasting a great amount of the evaporation material during mass production of OLEDs.

The present disclosure provides an evaporation crucible 2 and an evaporation system including the evaporation crucible 2, which are able to resolve the above problems.

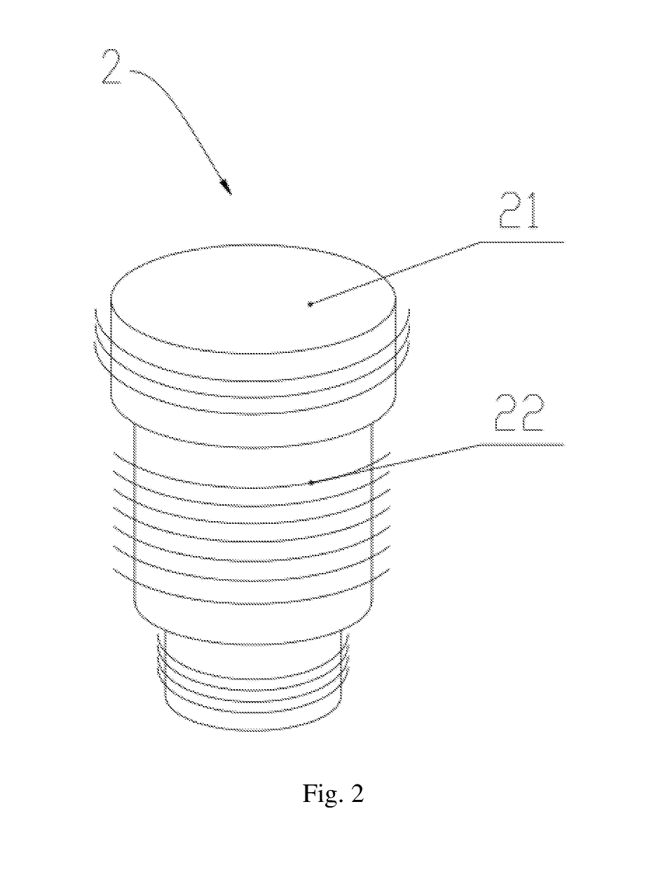

As shown in FIG. 2, the present disclosure provides the evaporation crucible 2. The evaporation crucible 2 includes a crucible body 21 and at least two heating means 22 wounded around the crucible body 21.

The crucible body 21 includes at least two cylindrical structures. The cylindrical structures have different diameters. The crucible body 21 is used to contain an evaporation material.

The heating means 22 are disposed respectively corresponding to the cylindrical structures. The heating means 22 heats the evaporation material in the corresponding cylindrical structure.

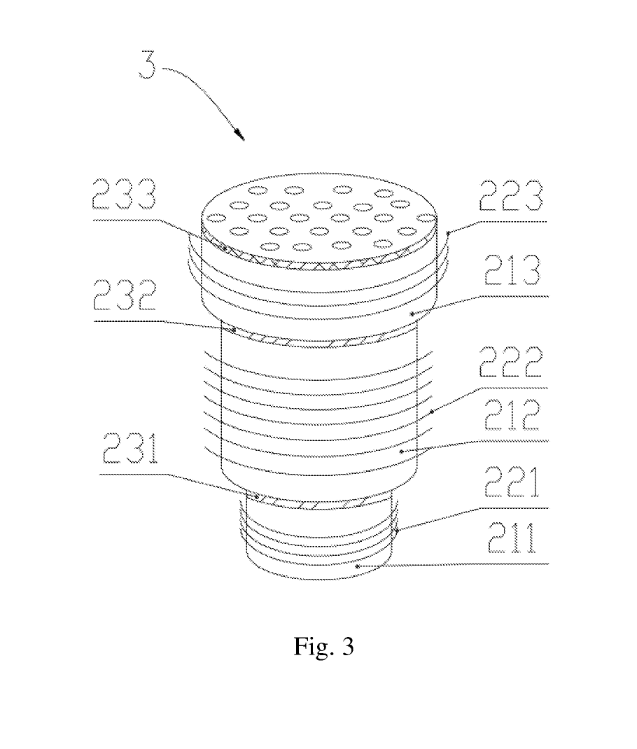

As shown in FIG. 3, the crucible body 21 includes at least two cylindrical structures. Each of the cylindrical structures is a heating area. The crucible body 21 includes three heating areas, that is, a first heating area 211, a second heating area 212, a third heating area 213. The first heating area 211 is a bottom heating area of the crucible body 21. The second heating area 212 is a middle heating area of the crucible body 21. The third heating area 213 is a top heating area of the crucible body 21. A diameter of the bottom heating area is shorter than a diameter of the middle heating area, and the diameter of the middle heating area is shorter than a diameter of the top heating area.

The advantage of such an arrangement is that a temperature of the evaporation material in the first heating area 211 rises faster because of a smaller diameter of the first heating area 211, so that heat of the evaporation material in the first heating area 211 will be transferred upwards to the evaporation material in the second heating area 212. Since the second heating area 212 has a larger diameter, portions of the evaporation material not being directly heated are more. A rising rate of a temperature of the evaporation material in the second heating area 212 is originally lower than a rising rate of the temperature of the evaporation material in the first heating area 211. However, the rising rate of the temperature of the evaporation material in the second heating area 212 that absorbs the heat from the first heating area 211 will be accelerated to achieve equilibrium between the rising rate of the temperature of the evaporation material in the first heating area 211 and the rising rate of the temperature of the evaporation material in the second heating area 212. Similarly, because the third heating area 213 has a largest diameter, the evaporation material in the third heating area 213 not being directly heated is even more. As a result, the rising rate of the temperature of the evaporation material in the third heating area 213 is the slowest. However, the second heating area 212 having a raised temperature will transfer heat to the third heating area 213, thus allowing the rising rate of the temperature of the evaporation material in the second heating area 213 to be equilibrium with the rising rate of the temperature of the evaporation material in the second heating area 212. In this manner, the rising rates of the temperatures of the evaporation material in the first heating area 211, the second heating area 212 and the third heating area 213 reach an equilibrium. Thus, a greater temperature difference is not generated along a longitudinal direction of the crucible body 21.

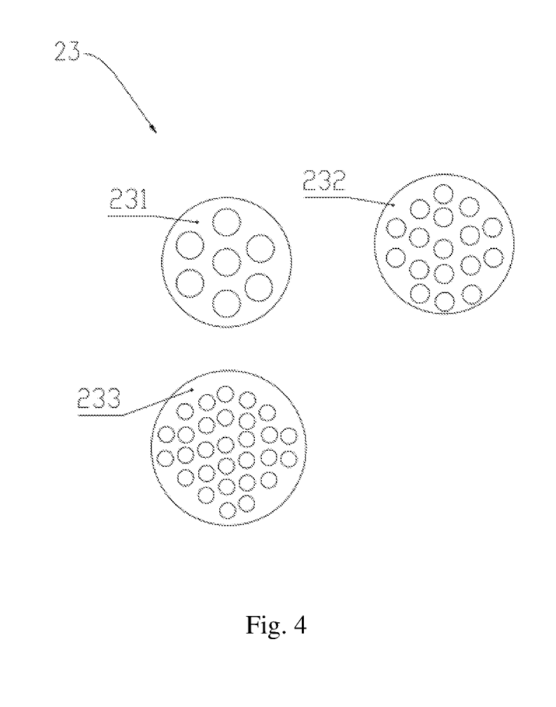

As shown in FIG. 4, in order to avoid the phenomena that the evaporation material in the crucible body suddenly boils and heating in a horizontal direction is not uniform, a sieve disc 23 is disposed on top of each of the heating areas.

In order to prevent clogging of circular openings of the sieve discs, a diameter of circular openings of a first sieve disc 231 is longer than a diameter of circular openings of a second sieve disc 231. The diameter of circular openings of the second sieve disc 231 is longer a diameter of circular openings of a first sieve disc 233. In addition, the circular openings of the sieve discs 23 are uniformly distributed in the sieve discs 23.

Both the sieve discs 23 and the crucible body 21 are made of a same material, such as titanium. In this manner, the sieve discs 23 and the crucible body 21 can have a same thermal conductivity, thus avoiding the occurrence of non-uniform thermal conduction across various parts of the evaporation crucible 2.

The heating means 22 include at least three heating means disposed along the longitudinal direction, that is, a first heating means 221, a second heating means 222 and a third heating means 223. At least two heating means 22 are uniformly disposed around the crucible body 21 so that separate and uniform heating of the first heating area 211, the second heating area 212 and the third heating area 213 can be achieved. The heating means 22 are usually heating wires.

The heating means 22 further include a temperature measurement and control part configured to measure and control a heating temperature of the first heating area 211, the second heating area 212 and the third heating area 213 separately.

The evaporation crucible 2 further includes a separation means for approaching or separating the heating means 22 and the crucible body 21.

The present disclosure further provides an evaporation system. The evaporation system includes the evaporation crucible 2. The evaporation crucible 2 may be the evaporation crucible 2 of any of the embodiments of the present disclosure.

The present disclosure provides an evaporation crucible and an evaporation system including the evaporation crucible. Not only can the excessively big temperature differences in the horizontal direction and longitudinal direction of the evaporation crucible in the evaporation system in the related art be improved, but the waste of evaporation material can be reduced. The material utilization rate is increased to reduce the production cost.

The present disclosure is described in detail in accordance with the above contents with the specific preferred examples. However, this present disclosure is not limited to the specific examples. For the ordinary technical personnel of the technical field of the present disclosure, on the premise of keeping the conception of the present disclosure, the technical personnel can also make simple deductions or replacements, and all of which should be considered to belong to the protection scope of the present disclosure.

1. An evaporation crucible comprising a crucible body and at least two heating means wounded around the crucible body;
the crucible body comprising at least two cylindrical structures, the cylindrical structures having different diameters, the crucible body being used to contain an evaporation material;
the heating means being disposed respectively corresponding to the cylindrical structures, the heating means heating the evaporation material in the corresponding cylindrical structure;
the heating means further comprising a temperature measurement and control part configured to measure and control a heating temperature of at least two heating areas, separately.

2. The evaporation crucible as claimed in claim 1, wherein the evaporation crucible further comprises at least two sieve discs, the sieve discs respectively correspond to the cylindrical structures, each of the sieve discs is disposed on top of the corresponding cylindrical structure and is configured to uniform flow of the evaporation material in the crucible body.

3. The evaporation crucible as claimed in claim 2, wherein both the sieve discs and the crucible body are made of titanium.

4. The evaporation crucible as claimed in claim 2, wherein each of the cylindrical structures is a heating area, the crucible body comprises three heating areas, the three heating areas are a first heating area, a second heating area and a third heating area, the first heating area is a bottom area of the crucible body, the second heating area is a middle area of the crucible body, the third heating area is a top area of the crucible body, a diameter of the first heating area is shorter than a diameter of the second heating area, and the diameter of the second heating area is shorter than a diameter of the third heating area.

5. The evaporation crucible as claimed in claim 4, wherein a height of the first heating area occupies 10% of a height of the crucible body, a height of the third heating area occupies 15% of the height of the crucible body.

6. The evaporation crucible as claimed in claim 4, wherein the sieve discs comprise a first sieve disc, a second sieve disc and a third sieve disc, the first sieve disc corresponds to the first heating area, the second sieve disc corresponds to the second heating area, the third sieve disc corresponds to the third heating area, an area of the first sieve disc is shorter than an area of the second sieve disc, and the area of the second sieve disc is shorter than an area of the third sieve disc.

7. The evaporation crucible as claimed in claim 6, wherein a diameter of circular openings of a first sieve disc is longer than a diameter of circular openings of a second sieve disc, and the diameter of circular openings of the second sieve disc is longer than a diameter of circular openings of a first sieve disc.

8. The evaporation crucible as claimed in claim 4, wherein the heating means comprise a first heating means, a second heating means and a third heating means disposed along a longitudinal direction, the first heating means, the second heating means and the third heating means are disposed respectively around the first heating area, the second heating area and the third heating area so that separate and uniform heating of the first heating area, the second heating area and the third heating area are achieved.

9. An evaporation crucible comprising a crucible body and at least two heating means wounded around the crucible body;
the crucible body comprising at least two cylindrical structures, the cylindrical structures having different diameters, the crucible body being used to contain an evaporation material;
the heating means being disposed respectively corresponding to the cylindrical structures, the heating means heating the evaporation material in the corresponding cylindrical structure.

10. The evaporation crucible as claimed in claim 9, wherein the evaporation crucible further comprises at least two sieve discs, the sieve discs respectively correspond to the cylindrical structures, each of the sieve discs is disposed on top of the corresponding cylindrical structure and is configured to uniform flow of the evaporation material in the crucible body.

11. The evaporation crucible as claimed in claim 10, wherein both the sieve discs and the crucible body are made of titanium.

12. The evaporation crucible as claimed in claim 10, wherein each of the cylindrical structures is a heating area, the crucible body comprises three heating areas, the three heating areas are a first heating area, a second heating area and a third heating area, the first heating area is a bottom area of the crucible body, the second heating area is a middle area of the crucible body, the third heating area is a top area of the crucible body, a diameter of the first heating area is shorter than a diameter of the second heating area, and the diameter of the second heating area is shorter than a diameter of the third heating area.

13. The evaporation crucible as claimed in claim 12, wherein a height of the first heating area occupies 10% of a height of the crucible body, a height of the third heating area occupies 15% of the height of the crucible body.

14. The evaporation crucible as claimed in claim 12, wherein the sieve discs comprise a first sieve disc, a second sieve disc and a third sieve disc, the first sieve disc corresponds to the first heating area, the second sieve disc corresponds to the second heating area, the third sieve disc corresponds to the third heating area, an area of the first sieve disc is shorter than an area of the second sieve disc, and the area of the second sieve disc is shorter than an area of the third sieve disc.

15. The evaporation crucible as claimed in claim 14, wherein a diameter of circular openings of a first sieve disc is longer than a diameter of circular openings of a second sieve disc, and the diameter of circular openings of the second sieve disc is longer than a diameter of circular openings of a first sieve disc.

16. The evaporation crucible as claimed in claim 12, wherein the heating means comprise a first heating means, a second heating means and a third heating means disposed along a longitudinal direction, the first heating means, the second heating means and the third heating means are disposed respectively around the first heating area, the second heating area and the third heating area so that separate and uniform heating of the first heating area, the second heating area and the third heating area are achieved.

17. An evaporation system comprising an evaporation crucible,
the evaporation crucible comprising a crucible body and at least two heating means wounded around the crucible body, wherein
the crucible body comprises at least two cylindrical structures, the cylindrical structures having different diameters, the crucible body is used to contain an evaporation material;
the heating means is disposed respectively corresponding to the cylindrical structures, the heating means heats the evaporation material in the corresponding cylindrical structure;
the heating means further comprises a temperature measurement and control part configured to measure and control a heating temperature of at least two heating areas, separately.
